(19) United States
(12) Patent Application Publication
(10) Pub. No.: US 2021/0203134 A1
(43) Pub. Date: Jul. 1, 2021

(54) Quantum Well Structure for Polarized Semiconductors

(71) Applicant: John Wasserbauer, Castro Valley, CA (US)

(72) Inventor: John Wasserbauer, Castro Valley, CA (US)

(21) Appl. No.: 16/731,722

(22) Filed: Dec. 31, 2019

(51) Int. Cl. H01S 5/34; H01S 5/20; H01S 5/32; H01L 33/06

(52) U.S. Cl. CPC H01S 5/34; H01L 33/06; H01S 5/3216; H01S 5/2013

(57) ABSTRACT

The invention relates to an apparatus, system and method for reducing or eliminating polarization effects in a compound semiconductor quantum well optical gain structure including the quantum confined Stark effect (QCSE) and carrier leakage effects. The system comprises a quantum well formed by a monotonic, stepwise and/or continuous compositional grading of a first quantum well interface toward a reduced bandgap, also including a monotonic, stepwise or continuous compositional grading of a second quantum well interface toward an increased bandgap thereby creating a quantum well shape that is substantially symmetric under the influence of electrostatic and/or electrodynamic fields. The system also comprises an electron blocking layer formed by a stepwise or continuous compositional grading starting from the maximum bandgap of the quantum well and increasing toward a larger bandgap, thereby creating a barrier shape with reduced electron sheet charge due to the influence of electrostatic fields.

### BACKGROUND OF THE INVENTION

### Field of the Invention

The invention relates to an apparatus, system and method for a quantum well active structure for polarized compound semiconductors, and, more particularly, a quantum well structure that remains substantially symmetric under the influence of electrostatic and/or electrodynamic fields. The invention further relates to a quantum well active structure with an electron blocking layer that does not support a large accumulation of electrons at its quantum well side interface under the influence of electrostatic fields.

### Background of the Invention

Compound semiconductors have achieved great success in realizing practical optoelectronic devices, such as lasers and detectors. Compounds based on III-V elements, such as InP and GaAs, have produced optoelectronic devices that emit light from the far infrared to visible (orange) wavelengths. For short wavelengths from the green to ultraviolet, larger bandgap semiconductors, such as the III-nitride compounds (InN, GaN and AlN), have been used. Whereas the former compounds have a non-polar, zinc-blend structure, the latter N-based compounds have a wurtzite lattice structure and exhibit both spontaneous and strain-induced (piezoelectric) polarization. As a consequence, large internal electrical fields appear between heterointerfaces leading to several detrimental effects for optoelectronic devices.

In an undoped, unpolarized quantum well the conduction and valence bands are flat (no built-in fields). The electron and hole wavefunctions are centered within the well and overlap perfectly, thereby providing the largest transition strength. In an undoped, polarized quantum well, however, the bottom of the well is tilted. The electron and hole wavefunctions are shifted toward the sides of the well in opposite directions, while the energy gap between them shrinks. This is known as the quantum confined Stark effect (QCSE) and results in a weaker transition and longer carrier lifetimes, leading to a reduction of the photon emission rate. This effect makes it difficult to fabricate a practical UV laser from these materials.

An additional drawback to polarized interfaces regards the electron blocking layer (EBL), which is intended to keep energetic electrons from escaping from the active region and recombining in the p-type cladding. The polarization at this layer attracts a large interface charge which pulls the conduction band down, thereby reducing the EBL barrier height. As a result, electron leakage is increased and device efficiency is reduced. This effect raises the threshold current of lasers and reduces the internal quantum efficiency of both lasers and light emitting diodes (LEDs).

The invention provides a means for countering both of these effects through the use of graded heterointerfaces, which spread the polarization-induced sheet charge into a quasi-volume space charge. This approach enables the creation of near-symmetrical, non-square quantum wells and a smooth transition to an EBL that does not trap a large, singular interface charge.

Scifres et al. U.S. Pat. No. 4,882,734 teaches a multiple quantum well superlattice having a sawtooth shape of continually varying compositional content. While similar to what herein is termed a “V-shaped well,” (a) it is not intended for the explicit purpose of mitigating the deleterious effects of polarization fields and (b) it exclusively applies to the AlGaAs material system, even though not explicitly stated in the claims. Further evidence of this resides in the facts that (a) Claim 8 explicitly refers to a “modulated grading in refractive index” as the primary goal of the MQW structure, (b) FIG. 6 shows a smoothly varying band structure as a result of the continually varying compositional content, which is not possible in polarized materials, and (c) the sawtooth shape of each well is perfectly symmetric, which is also not possible in polarized materials. It is therefore not obvious that the Scifres disclosure should be applied to an entirely different problem (polarization effects) in an entirely different class of materials (polarized semiconductors).

### SUMMARY OF INVENTION

The invention provides a system for reducing or eliminating polarization effects, primarily the quantum confined Stark effect (QCSE) and carrier leakage effect, in a compound semiconductor quantum well optical gain structure. In one embodiment, a quantum well is formed by a stepwise or continuous compositional grading of a first quantum well interface toward a reduced bandgap, followed by a monotonic, stepwise or continuous compositional grading of a second quantum well interface toward an increased bandgap. An electron barrier layer is formed by a stepwise or continuous compositional grading, starting from the maximum bandgap of the quantum well and increasing toward a larger bandgap.

### BRIEF DESCRIPTION OF THE DRAWINGS

In the drawings, like numerals describe like components throughout the several views:

FIG. 1 is a band diagram illustrating a quantum well without (a) and with (b) polarization effects;

FIG. 2 is a band diagram illustrating a light emitting device, including a multiple quantum well active region and an electron blocking layer without (a) and with (b) polarization effects;

FIG. 3 is a band diagram illustrating a graded, U-shaped, multiple quantum well: (a) idealized band structure and (b) stepwise digital approximation without polarization, (c) stepwise digital approximation with polarization;

FIG. 4. is a band diagram illustrating a graded, V-shaped, multiple quantum well: (a) idealized band structure and (b) stepwise digital approximation without polarization, (c) stepwise digital approximation with polarization;

FIG. 5. is a band diagram illustrating a graded, Y-shaped, multiple quantum well: (a) idealized band structure and (b) stepwise digital approximation without polarization, (c) stepwise digital approximation with polarization;

FIG. 6. is a conduction band diagram illustrating a graded electron blocking layer (a) idealized band structure and (b) stepwise digital approximation without polarization, (c) stepwise digital approximation with polarization;

FIG. 7 is a band diagram illustrating a graded multi-quantum well with graded electron blocking layer (a) idealized band structure and (b) stepwise digital approximation without polarization, (c) stepwise digital approximation with polarization;

### DETAILED DESCRIPTION OF THE EMBODIMENTS

Non-limiting embodiments of the invention will be described below with reference to the accompanying drawings, wherein like reference numerals represent like elements throughout. While the invention has been described in detail with respect to the preferred embodiments thereof, it will be appreciated that upon reading and understanding of the foregoing, certain variations to the preferred embodiments will become apparent, which variations are nonetheless within the spirit and scope of the invention. The drawings featured in the figures are provided for the purposes of illustrating some embodiments of the invention, and are not to be considered as limitation thereto.

The invention provides a device, apparatus, system and method for using an interface grading scheme for reducing or eliminating the negative effects of polarization, primarily the quantum confined Stark effect (QCSE) and carrier leakage effect, in a compound semiconductor quantum well structure. Regarding the QCSE, the invention provides a quantum well structure that remains substantially symmetric under the influence of electrostatic and/or electrodynamic fields. In one embodiment, a first layer of monotonically and either stepwise or continuously decreasing bandgap is disposed on a suitable substrate or structure, such as a partially grown laser diode or LED layer stack. A second layer of monotonically and either stepwise or continuously increasing bandgap is disposed on the first layer. Together the layers form a non-square shaped quantum well.

Regarding the carrier leakage effect, the invention provides for a graded transition from a radiative recombination active region to an EBL. In one embodiment, a layer of monotonically and either stepwise or continuously increasing bandgap is disposed on a quantum well, barrier, or separate confinement layer. The resulting band structure has a reduced or eliminated kink at this heterointerface. As a result, there is a substantially reduced electron accumulation and attendant lowering of the barrier height of the EBL, rendering it more effective at blocking carrier leakage.

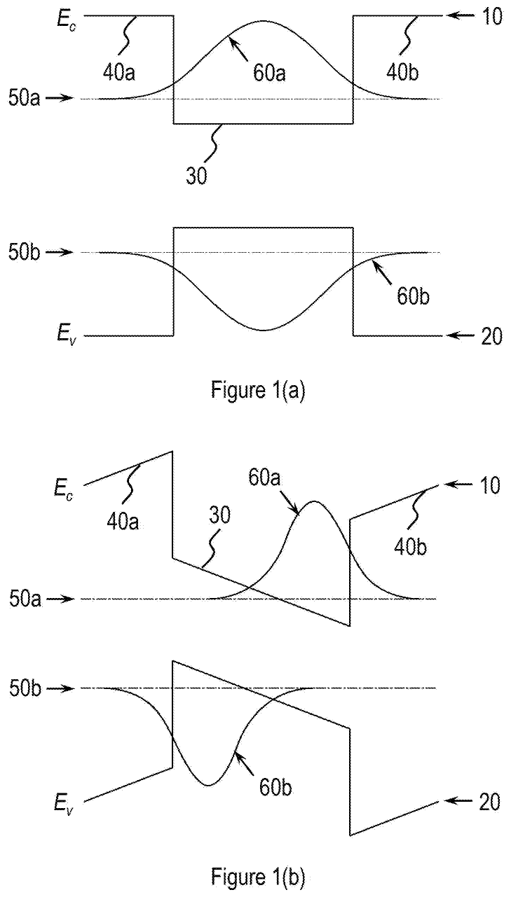

FIGS. 1(a)-1(b) illustrate the effect of polarization on the band structure of a quantum well. FIG. 1(a) exhibits the conduction and valence band diagrams 10, 20 of a quantum well, which comprises a layer of narrow bandgap material 30 surrounded by layers of larger bandgap 40ab, also called barriers. Without polarization, the conduction 10 and valence 20 band edges are flat (horizontal) while the bandgap transitions are stepwise (vertical) changes in the gap between electron and hole bands. Also shown are the quantum levels 50ab and wavefunctions 60ab, the latter being symmetric within the quantum well. Referring to FIG. 1(b), under the influence of polarization a downward step in bandgap, as between layer 40a and layer 30, causes a negative polarization at the interface, which attracts a positive sheet charge, producing a change in the band structure, such as, for example a clockwise kink in the band structure. The slope of the bands on either side of the heterointerface must be of opposite sign, in this case positive on the left and negative on the right. An upward step in bandgap, such as between layer 30 and layer 40b, does the opposite. Between the interfaces band tilting and/or bending must occur to satisfy these constraints. FIG. 1(b) also illustrates the effect of this band distortion on the quantum levels 50 and wavefunctions 60; the electron 50a and hole 50b quantum levels are drawn closer to each other, while the electron 60a and hole 60b wavefunctions are shifted toward opposite sides of the well 30. This is known as the quantum confined Stark effect (QCSE).

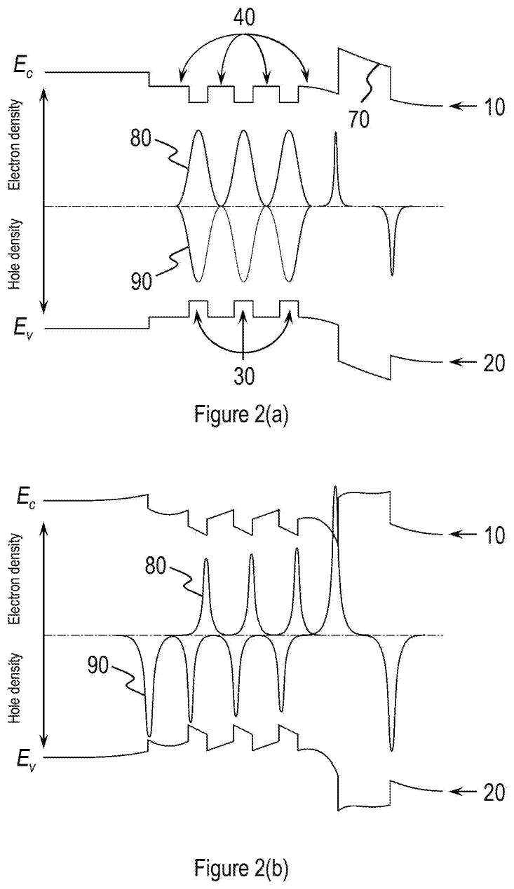

FIGS. 2(a)-2(b) illustrate the band diagram for a typical III-N light-emitting device, such as a LED or laser diode. FIG. 2(a) illustrates the unbiased device without polarization effects. The structure includes a multiple quantum well (MOW) active region comprised of wells 30 and barriers 40. An EBL 70 is disposed on the active region in order to reduce or eliminate electron leakage into the p-type cladding layer (to the right). Also shown are the electron 80 and hole 90 densities which overlap perfectly within the MQWs. Because of the doping related band bending, some electron and hole sheet charge is concentrated around the EBL. In FIG. 2(b) polarization effects cause heavy distortion in the band structure. The electron 80 and hole 90 densities are plotted along the length of the device. The separation of the electron and hole populations within the quantum well are evident, as in FIG. 1(b). In addition, a large accumulation of electrons appears at the active region/EBL interface, causing additional band bending at this interface, and lowering the barrier height significantly. The QCSE reduces the strength of the quantum transition and increases the carrier lifetime. For a laser diode, this increases the threshold current and reduces the speed at which the laser can be modulated. The lowering of the EBL barrier height has the negative effect of allowing a large leakage current, also increasing the threshold current for lasers and reducing the internal quantum efficiency of both lasers and LEDs.

Consequently, to mitigate the effects of the QCSE, the invention provides for an apparatus, system and method for a quantum well structure for polarized material compound semiconductors having a quantum well shape that is substantially symmetric and relatively invariant under the effects of electrostatic or electrodynamic fields. The apparatus, system and method extends to equivalent structures having any symmetric shape without a significantly flat bottom, whereby any symmetric shape that touches a horizontal tangent at the bottom at a single point will suffice. The intent of this design is to maximize the overlap between the electron and hole wavefunctions as achieved by grading of the sides and bottom of the quantum well. The shape of the graded region may be linear or non-linear (e.g. superlinear, sublinear, or S-shaped).

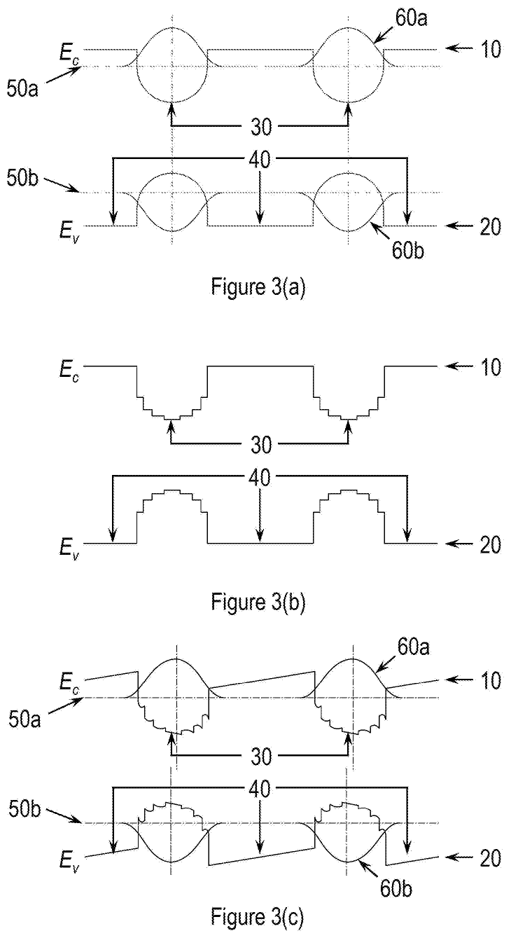

In a first embodiment, FIGS. 3(a), 3(b), and 3(c) illustrate one or more quantum wells comprising a U-shaped version of a graded quantum well, grown from left to right, according to the invention. FIG. 3(a) exhibits the ideal case a U-shaped well with a rounded bottom. The conduction 10 and valence 20 bands are perfectly symmetric about the center of the wells 30. For multiple quantum wells, a certain minimum (not zero) thickness barrier layer 40 must be inserted between multiple quantum wells in order to prevent mini-band formation and retain a step-like density of states. Also shown are the quantum levels 50ab and wavefunctions 60ab, the latter being symmetric within the quantum wells. FIG. 3(b) illustrates a non-polar, stepwise approximation of this shape using digital alloys. From a first, barrier-level bandgap a series of layers with decreasing bandgap are grown. At the bottom of the well the grading is reversed and upward steps are used to return to the starting bandgap. The result resembles a distorted staircase. There is a limit to how low the bandgap can be at the bottom of the well, because for an In content of more than about 30% spontaneous ordering of the atoms occurs, leading to non-homogeneous alloys. Finally, in FIG. 3(c), the effects of polarization are added. This yields a structure with notable asymmetries. First, the steps of the downward and upward grades have different shapes. Second, at the bottom of the well an electrostatic field is present in the layer with the smallest bandgap, producing a tilt in the bands as in the case of a square well. These effects cannot be completely eliminated. However, as the step size becomes smaller and smaller, the band structure more closely approximates a continuously graded transition, as defined by the smooth lines of FIG. 3(a). The practical limit for digital grading is monolayer step sizes, which, in a typical well, represents approximately 10 steps: 5 down, 5 up.

Additionally, FIG. 3(c) shows the first electron 50a and hole 50b quantized levels and wavefunctions. In the invention, the shape of the well is designed to align the electron 60a and hole 60b wavefunctions with respect to each other. This can be largely achieved even with digitally graded (monolayer or greater) interfaces because the wavefunctions are spread over distances much larger than the step size. For a U-shaped well with constant bandgap barriers, however, the electrostatic fields in the barriers will shift the electron and hole wavefunctions in opposite directions by a small amount, as shown by a spatial separation in the wavefunction peaks.

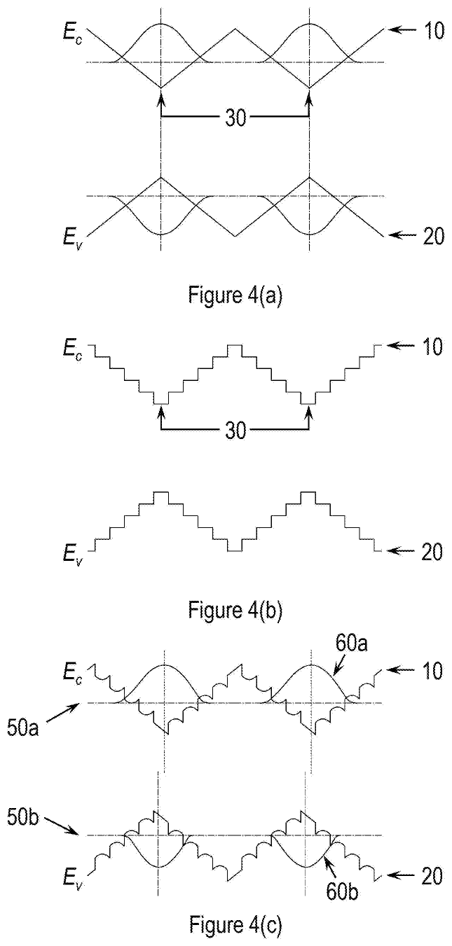

In another embodiment, FIGS. 4(a), 4(b), and 4(c) illustrate a V-shaped version of a graded quantum well, grown from left to right, according to the invention. FIG. 4(a) exhibits the ideal case of a V-shaped well with a pointed bottom. The conduction 10 and valence 20 bands are perfectly symmetric about the center of the wells 30. Also shown are the quantum levels 50ab and wavefunctions 60ab, the latter being symmetric within the quantum wells. For multiple quantum wells of sufficient width, no barrier layer is required between wells as the wavefunctions will have sufficient separation. FIG. 4(b) illustrates a non-polar, stepwise approximation of this shape using digital alloys. From a first, barrier-level bandgap a series of layers with decreasing bandgap are grown. At the bottom of the well the grading is reversed and upward steps are used to return to the starting bandgap. Finally, in FIG. 4(c), the effects of polarization are added. Once again, we note that the steps of the downward and upward grades have different shapes. Also, at the bottom of the well an electrostatic field is present in the layer with the smallest bandgap, producing a tilt in the bands, as in the case of a square well. Because of these asymmetries, the electron 60a and hole 60b wavefunctions are shifted in opposite directions by a small amount. The practical limit for digital grading is monolayer step sizes, which, in a typical V-shaped well, represents approximately 20 steps: 10 down, 10 up.

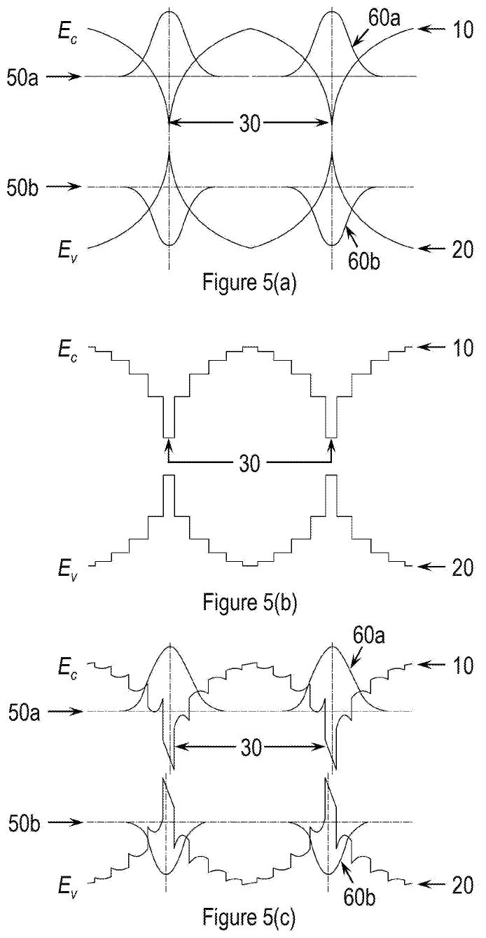

In another embodiment, FIGS. 5(a), 5(b), and 5(c) illustrate a Y-shaped version of a graded quantum well, grown from left to right, according to the invention. FIG. 5(a) exhibits the ideal case a Y-shaped well with a pointed bottom. The conduction 10 and valence 20 bands are perfectly symmetric about the center of the wells 30. Also shown are the quantum levels 50ab and wavefunctions 60ab, the latter being symmetric within the quantum wells. For multiple quantum wells of sufficient width, no barrier layer is required between wells as the wavefunctions will have sufficient separation. FIG. 5(b) illustrates a non-polar, stepwise approximation of this shape using digital alloys. From a first, barrier-level bandgap a series of layers with decreasing bandgap are grown. At the bottom of the well the grading is reversed and upward steps are used to return to the starting bandgap. The practical limit for digital grading is monolayer step sizes, which, in a typical Y-shaped well, represents approximately 20 steps: 10 down, 10 up. Finally, in FIG. 5(c), the effects of polarization are added. Once again, we note that the steps of the downward and upward grades have different shapes. Also, at the bottom of the well an electrostatic field is present in the layer with the smallest bandgap, producing a tilt in the bands, as in the case of a square well. As a result of these asymmetries, the electron 60a and hole 60b wavefunctions are shifted in opposite directions by a small amount.

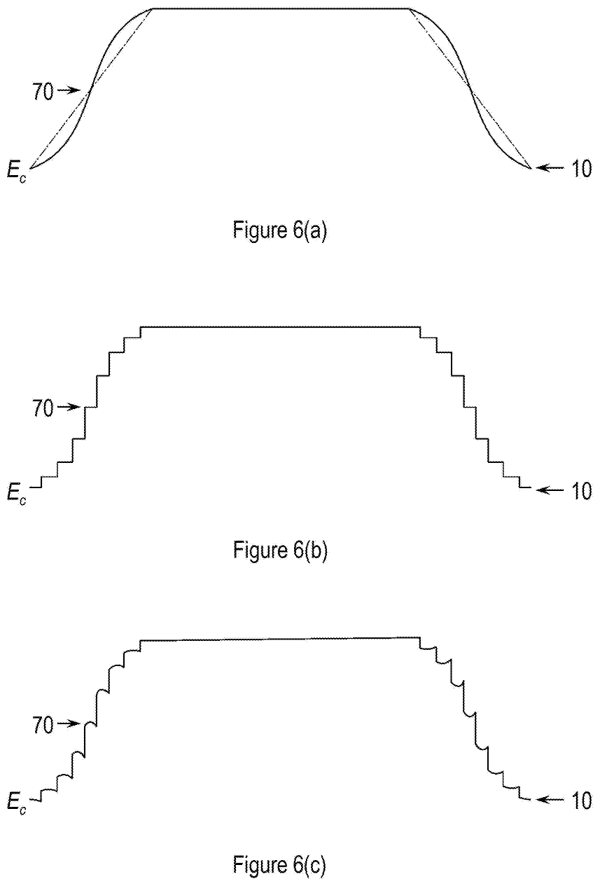

Referring to FIGS. 6(a), 6(b), and 6(c), the invention provides for reducing or eliminating the detrimental effect of polarization on the barrier height of an EBL by means of a graded heterointerface. In FIG. 2(b) the EBL barrier lowering is due to the sheet charge accumulation at the large, positive step in bandgap at the EBL heterointerface. Grading of this interface converts the sheet charge into a quasi-space-charge. In FIG. 6(a) for example, the conduction band 10 of graded EBL interface 70, which may be linear, such as the dashed line, or non-linear, as in the S-shaped solid line. FIG. 6(b) illustrates a non-polar, stepwise approximation of the latter using digital alloys. In FIG. 6(c) the effects of polarization are added. The graded interface may be disposed on a quantum barrier layer or may simply be a continuation of a graded quantum well. If disposed on a thick layer of constant bandgap, there may be a polarization kink in the bands at the heterointerface. To minimize this, only small increments in bandgap should be used to grade the interface.

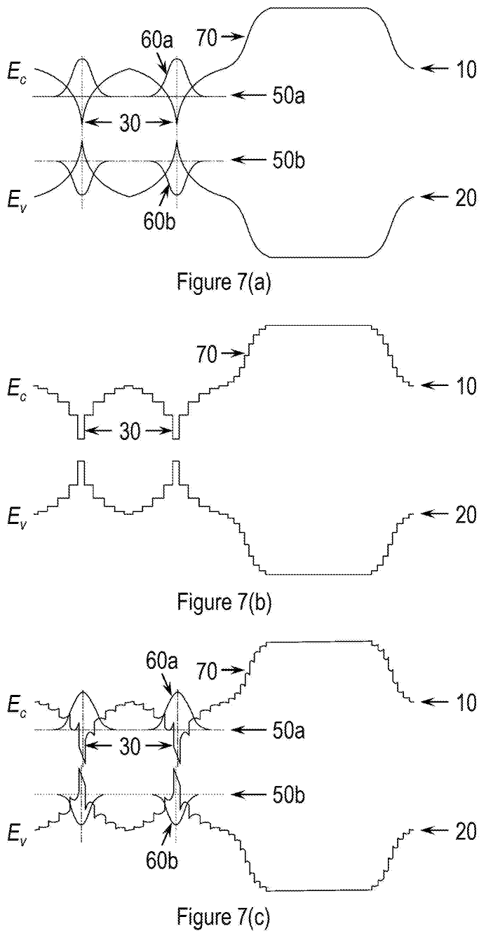

An example of a device with multiple graded wells and a graded EBL is given in FIGS. 7(a), 7(b), and 7(c). FIG. 7(a) shows the idealized conduction 10 and valence 20 bands of a Y-graded MQW 30 active region and S-graded EBL 70. In this embodiment, the slopes of the bands between the rightmost QW and EBL are continuous. FIG. 7(b) illustrates a non-polar, stepwise approximation of this structure using digital alloys. In FIG. 7(c), the effects of polarization are added. We note the absence of a large notch in the conduction band 10 between the QW 30 and EBL 70. In this way, barrier lowering is substantially reduced.

The previous description of the disclosed embodiments is provided to enable any person skilled in the art to make or use the invention. Various modifications to these embodiments will be readily apparent to those skilled in the art, and the generic principles defined herein can be applied to other embodiments without departing from the spirit or scope of the invention. It is therefore desired that the present embodiments be considered in all respects as illustrative and not restrictive, reference being made to the appended claims as well as the foregoing descriptions to indicate the scope of the invention.

1. A device comprising: one or more graded quantum wells in a polarized material wherein each quantum well comprises conduction and valence band shapes having the property that they remain substantially symmetric under the influence of electrostatic and/or electrodynamic fields.

2. The quantum well of claim 1 in which the grading produces a rounded or point-like well bottom, such as in a U, V or Y-shaped well.

3. A device comprising: a graded electron blocking layer wherein said barrier shape substantially reduces electron accumulation at its quantum well side interface under the influence of electrostatic fields.

4. The electron blocking layer of claim 3 in which the grading is of linear or non-linear shape.

5. The device of claims 1 & 3 comprising: one or more graded quantum wells in a polarized material wherein each quantum well comprises a quantum well shape that is substantially symmetric under the influence of electrostatic and/or electrodynamic fields and a graded electron blocking layer wherein said barrier shape substantially reduces electron accumulation at its quantum well side interface under the influence of electrostatic fields.
